(19) United States
(12) Patent Application Publication
(10) Pub. No.: US 2026/0198068 A1
(43) Pub. Date: Jul. 9, 2026

(54) SEMICONDUCTOR DEVICE AND METHOD OF MANUFACTURING THE SAME

(71) Applicant: Samsung Electronics Co., Ltd., Suwon-si (KR)

(72) Inventors: Jaehong LEE, Suwon-si (KR); Changseok LEE, Suwon-si (KR); Sangwon KIM, Suwon-si (KR); Jaewon KIM, Suwon-si (KR); Taehoon KIM, Suwon-si (KR); Woochang LEE, Suwon-si (KR); Yoonhoo HA, Suwon-si (KR)

(73) Assignee: Samsung Electronics Co., Ltd., Suwon-si (KR)

(21) Appl. No.: 19/297,647

(22) Filed: Aug. 12, 2025

(30) Foreign Application Priority Data
Jan. 7, 2025 (KR) 10-2025-0002383

(51) Int. Cl. H10D 84/01; H10D 30/00; H10D 30/01; H10D 62/10; H10D 84/83; H10D 84/85

(52) U.S. Cl. CPC H10D 84/0151; H10D 84/0188; H10D 84/833; H10D 84/852; H10D 30/0191; H10D 30/502; H10D 62/121

(57) ABSTRACT

Provided are a semiconductor device and/or a method of manufacturing the semiconductor device. The semiconductor device may include a first nanosheet stack on a first region of a substrate and a second nanosheet stack on a second region, a first gate structure crossing the first nanosheet stack on the first region, a second gate structure crossing the second nanosheet stack on the second region, and a dielectric wall extending in a first direction between the first region and the second region. The dielectric wall may separate the first nanosheet stack and the second nanosheet stack from each other. The dielectric wall may include a boron nitride layer having an amorphous phase. The first nanosheet stack and the second nanosheet stack each may include a plurality of nanosheet spaced apart from each other in a second direction. The second direction may cross the first direction.

### CROSS-REFERENCE TO RELATED APPLICATION

This application is based on and claims priority under 35 U.S.C. § 119 to Korean Patent Application No. 10-2025-0002383, filed on Jan. 7, 2025, in the Korean Intellectual Property Office, the disclosure of which is incorporated by reference herein in its entirety.

### BACKGROUND

### 1. Field

The disclosure relates to a semiconductor device and/or a method of manufacturing the same.

### 2. Description of the Related Art

With the rapid down-scaling of semiconductor devices, ensuring operation accuracy as well as fast operating speed in semiconductor devices may be advantageous. Also, with the increase of the integration degree and the decrease in size of semiconductor devices, a new structure capable of improving the performance and reliability of nanosheet field-effect transistors may be advantageous.

### SUMMARY

Provided are a semiconductor device with stabilized performance and/or improved reliability in a nanosheet field-effect transistor and/or a method of manufacturing the semiconductor device.

Additional aspects will be set forth in part in the description which follows and, in part, will be apparent from the description, or may be learned by practice of the presented embodiments of the disclosure.

According to an embodiment of the present disclosure, a semiconductor device may include a substrate including a first region and a second region; a plurality of nanosheets extending in a first direction on the substrate, the plurality of nanosheets including a first nanosheet stack on the first region and a second nanosheet stack on the second region, the plurality of nanosheets in the first nanosheet stack being spaced apart from each other in a second direction, the second direction crossing the first direction, the plurality of nanosheets in the second nanosheet stack being spaced apart from each other in the second direction; a first gate structure crossing the first nanosheet stack on the first region; a second gate structure crossing the second nanosheet stack on the second region; and a dielectric wall extending in the first direction on a portion of the substrate between the first region and the second region, the dielectric wall separating the first nanosheet stack and the second nanosheet stack from each other, and the dielectric wall including a boron nitride layer having an amorphous phase.

In some embodiments, a peak half width of the boron nitride layer may be 20 cm−1 or more in a region of 1,350 cm−1 to 1,400 cm−1 of a Raman spectrum.

In some embodiments, a dielectric constant of the boron nitride layer may be 3 or less.

In some embodiments, a ratio of a height of the dielectric wall with respect to a width of the dielectric wall may be 9 or more.

In some embodiments, a width of the dielectric wall may be 50 nm or less.

In some embodiments, the dielectric wall may include a first film arranged on a lower surface and both side surfaces of the dielectric wall and including a trench, and a second film filling the trench.

In some embodiments, the dielectric wall may include a first film and a second film. The first film may contact a lower surface of the second film, a first side surface of the second film, and a second side surface of the second film. The first side surface of the second film may be opposite the second side surface of the second film.

In some embodiments, the first film may include at least one of silicon oxide, silicon nitride, or silicon oxynitride, and the second film may include the boron nitride layer.

In some embodiments, a width of the first film may be greater than a width of the second film.

In some embodiments, the semiconductor device may further include a first insulating layer between the substrate and the first nanosheet stack; and a second insulating layer between the substrate and the second nanosheet stack.

In some embodiments, the first insulating layer, the second insulating layer, or both the first insulating layer and the second insulating layer may include at least one of silicon oxide, silicon nitride, or silicon oxynitride.

In some embodiments, at least one of the first nanosheet stack and the second nanosheet stack may be in contact with the dielectric wall.

In some embodiments, the first nanosheet stack, the second nanosheet stack, or both the first nanosheet stack and the second nanosheet stack may include a two-dimensional semiconductor material.

In some embodiments, the two-dimensional semiconductor material may include at least one of graphene, black phosphorous, phosphorene, transition metal dichalcogenide, and tellurene.

In some embodiments, the semiconductor device may further include

a first fin activation region arranged between the substrate and the first nanosheet stack in the first region; and a second fin activation region between the substrate and the second nanosheet stack in the second region. At least one of the first fin activation region and the second fin activation region may be doped with a p-type dopant, and an other of the first fin activation region and the second fin activation region is doped with an n-type dopant.

According to an embodiment, a method of manufacturing a semiconductor device may include alternately stacking a plurality of sacrificial layers and a plurality of nanosheets on a substrate; forming a first nanosheet stack and a second nanosheet stack by forming a first trench through the plurality of sacrificial layers and the plurality of nanosheets to expose the substrate; forming a dielectric wall in the first trench, the forming the dielectric wall including a process of forming a boron nitride layer having an amorphous phase in the first trench using an atomic layer deposition (ALD) process; removing the plurality of sacrificial layers; and forming a first gate structure surrounding the first nanosheet stack and a second gate structure surrounding the second nanosheet stack.

In some embodiments, the boron nitride layer may have a peak half width of 20 cm⁻¹ or more in a region of 1,350 cm⁻¹ to 1,400 cm⁻¹ of a Raman spectrum.

In some embodiments, a ratio of a height of the dielectric wall to a width of the dielectric wall may be 9 or greater.

In some embodiments, a width of the dielectric wall may be 50 nm or less.

In some embodiments, the forming the dielectric wall may include forming a first film in the first trench, the first film defining a second trench and contact with the first nanosheet stack and the second nanosheet stack; and forming the boron nitride layer as a second film filling the second trench.

In some embodiments, the first film may include at least one of silicon oxide, silicon nitride, or silicon oxynitride.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a layout of a semiconductor device according to an embodiment;

FIG. 2 is a cross-sectional view of the semiconductor device taken along line A-A of FIG. 1;

FIG. 3 is a cross-sectional view of the semiconductor device taken along line B-B of FIG. 1;

FIG. 4 is a cross-sectional view of the semiconductor device taken along line C-C of FIG. 1;

FIG. 5 is a cross-sectional view of a semiconductor device according to another embodiment; and

FIGS. 6 to 13 are reference diagrams illustrating a method of manufacturing the semiconductor device of FIG. 5.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a semiconductor device and a method of manufacturing the same according to embodiments are described in detail with reference to accompanying drawings. In the drawings, like reference numerals denote like components, and sizes of components in the drawings may be exaggerated for convenience of explanation.

Singular forms include plural forms unless apparently indicated otherwise contextually. It will be further understood that when a portion is referred to as “comprising” another component, the portion may not exclude another component but may further comprise another component unless the context states otherwise. Also, in the drawings, a size or thickness of each component may be exaggerated for clarity of description. In the following description, when a layer is described to exist on a substrate 100 or another layer, the layer may exist directly on the substrate 100 or the other layer or another layer may be interposed therebetween. In addition, because materials forming each layer in the following embodiments are non-limiting examples, other materials may be used.

Also, the terms “. . . unit”, “. . . module” used herein specify a unit for processing at least one function or operation, and this may be implemented with hardware or software or a combination of hardware and software.

The particular implementations shown and described herein are illustrative examples of the embodiments and are not intended to otherwise limit the technical scope of the embodiments in any way. For the brevity of the specification, the description of conventional electronic configurations, control systems, software, and other functional aspects of the systems may be omitted.

Connections of lines or connection members between components shown in the drawings are illustrative of functional connections and/or physical or circuit connections, and in practice, may be represented as alternative or additional various functional connections, physical connections, or circuit connections.

The use of the term of “the above-described” and similar indicative terms may correspond to both the singular forms and the plural forms.

Also, the steps of all methods described herein may be performed in any suitable order unless otherwise indicated herein or otherwise clearly contradicted by context. Also, the use of all exemplary terms (for example, etc.) is only to describe a technical spirit in detail, and the scope of rights is not limited by these terms unless the context is limited by the claims.

Expressions such as “at least one of,” when preceding a list of elements, modify the entire list of elements and do not modify the individual elements of the list. For example, the expression, “at least one of A, B, and C,” as well as similar language (e.g., “at least one of A, B, or C”), should be understood as including only A, only B, only C, or a combination of two or more of A, B, and C such as ABC, AB, BC, or AC.

When the terms “about” or “substantially” are used in this specification in connection with a numerical value, it is intended that the associated numerical value include a tolerance of ±10% around the stated numerical value. Moreover, when the words “generally” and “substantially” are used in connection with geometric shapes, it is intended that precision of the geometric shape is not required but that latitude for the shape is within the scope of the disclosure. Additionally, regardless of whether a value or shape is limited by “about” or “substantially,” such value and shape may be construed to include manufacturing or operating tolerance (e.g., ±10%) around the stated numerical value.

It will be understood that although the terms “first” and “second” are used herein to describe various elements, these elements should not be limited by these terms. Terms are only used to distinguish one element from other elements.

The use of any and all examples, or example language provided herein, is intended merely to better illuminate the disclosure and does not pose a limitation on the scope of the present disclosure unless otherwise claimed.

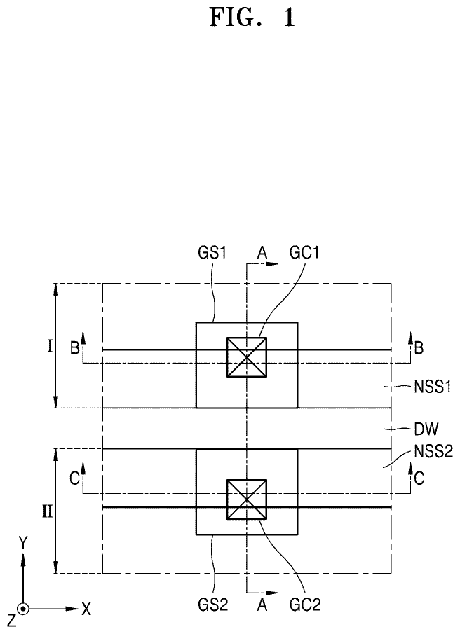

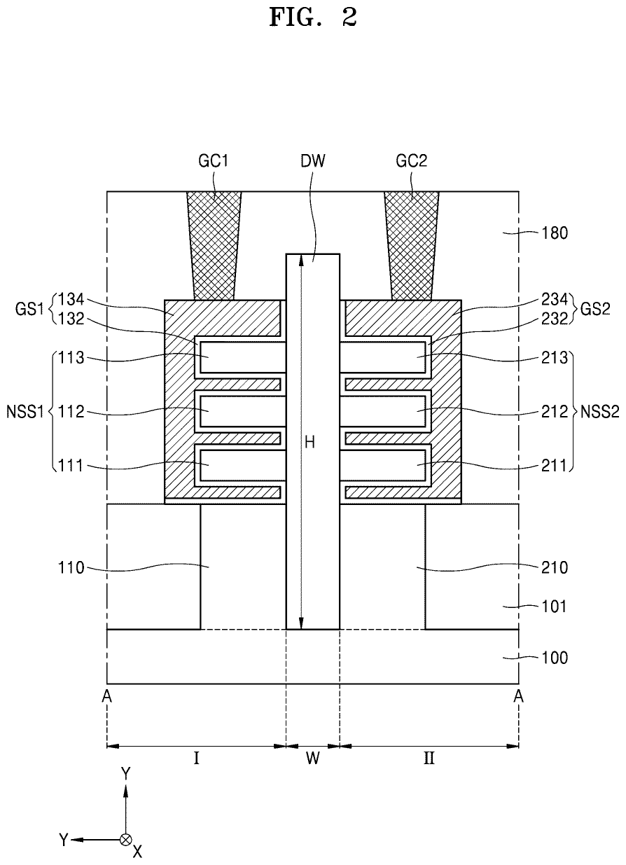

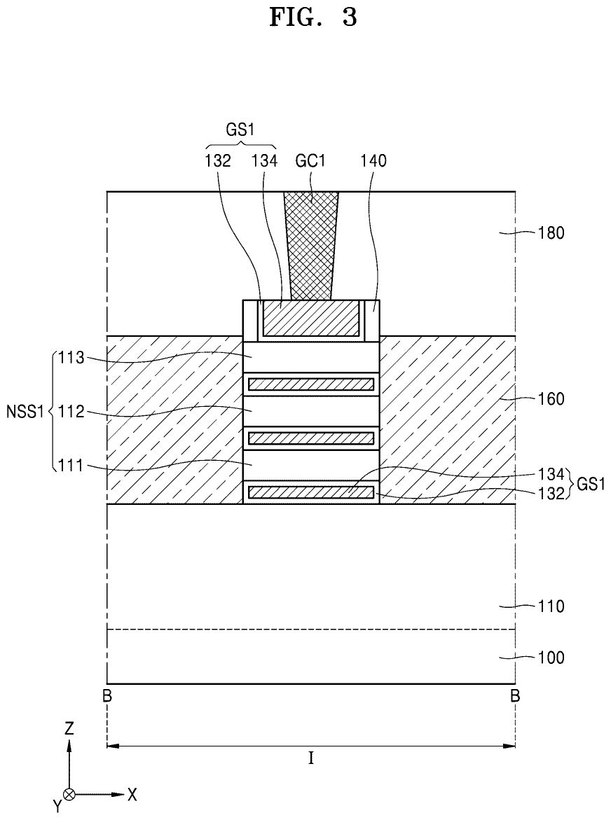

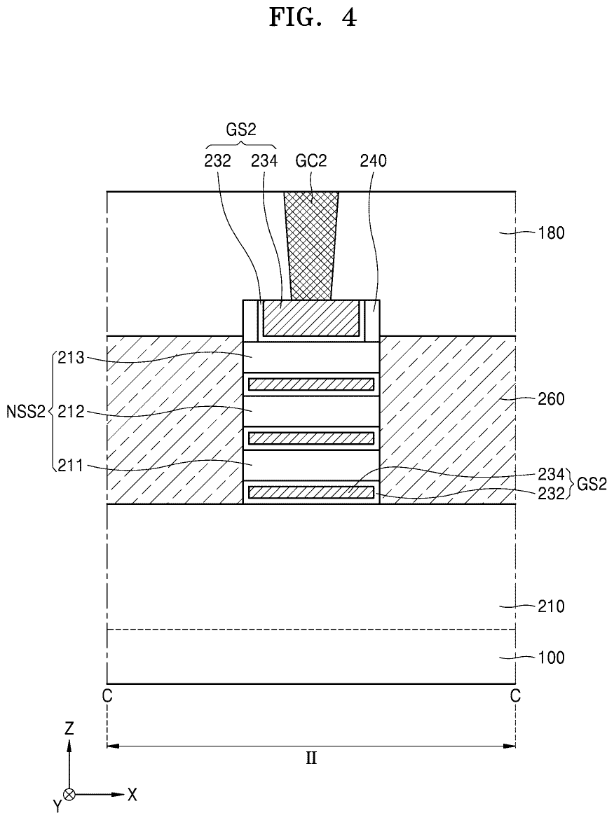

FIG. 1 is a layout of a semiconductor device according to an embodiment, FIG. 2 is a cross-sectional view of the semiconductor device taken along line A-A of FIG. 1, FIG. 3 is a cross-sectional view of the semiconductor device taken along line B-B of FIG. 1, and FIG. 4 is a cross-sectional view of the semiconductor device taken along line C-C of FIG. 1.

Referring to FIG. 1 to FIG. 4, the semiconductor device may include a substrate 100. The substrate 100 may include bulk silicon or silicon-on-insulator (SOI). In another embodiment, the substrate 100 may be a silicon substrate or may include another material, for example, silicon germanium, silicon germanium on insulator (SGOI), indium antimony, lead telluride compound, indium arsenide, indium phosphide, gallium arsenide, or gallium antimony. Alternatively, the substrate 100 may include an epitaxial layer formed on a base substrate. For convenience of description, the substrate 100 is described hereinafter as being a silicon substrate.

The substrate 100 may include a first region I and a second region II. The first region I and the second region II may be separated from each other based on a dielectric wall DW that is described later. For example, the dielectric wall DW may extend in a first direction (X) that is parallel to an upper surface of the substrate 100, and the first region I and the second region II may be arranged in a second direction (Y) crossing the first direction (X) based on the dielectric wall DW. That is, the first region I may be a region of the substrate 100, which is defined on one side of the dielectric wall DW, and the second region II may be a region of the substrate 100 defined on the other side of the dielectric wall DW.

For example, transistors of different conductive types may be formed in the first region I and the second region II. For example, the first region I may be an n-channel field effect transistor (NFET) region and the second region II may be a p-channel field effect transistor (PFET) region. In another example, the first region I may be a PFET region and the second region II may be an NFET region. However, one or more embodiments are not limited thereto. In some embodiments, transistors of the same conductive type may be formed in the first region I and the second region II.

In some embodiments, the semiconductor device may further include a first nanosheet stack NSS1 and a second nanosheet stack NSS2.

The first nanosheet stack NSS1 may be formed on the first region I of the substrate 100. The first nanosheet stack NSS1 may extend in the first direction X. The first nanosheet stack NSS1 may include a plurality of nanosheets (e.g., first to third nanosheets 111, 112, and 113) that are sequentially stacked above the upper surface of the substrate 100 and respectively extend in the first direction X while being spaced apart from each other. The first nanosheet stack NSS1 may be provided as a channel region of a multi-bridge channel field effect transistor (MBCFET) including a multi-bridge channel. The number of nanosheets included in the first nanosheet stack NSS1 is an example, and is not limited thereto.

The second nanosheet stack NSS2 may be formed in the second region II on the substrate 100. The second nanosheet stack NSS2 may extend in the first direction X. The second nanosheet stack NSS2 may include a plurality of nanosheets (e.g., fifth to seventh nanosheets 211, 212, and 213) that are sequentially stacked above the upper surface of the substrate 100 and respectively extend in the first direction X while being spaced apart from each other. The second nanosheet stack NSS2 may be provided as a channel region of the MBCFET including the multi-bridge channel. The number of nanosheets included in the second nanosheet stack NSS2 is an example, and is not limited thereto.

In FIG. 2, a width of the first nanosheet stack NSS1 and a width of the second nanosheet stack NSS2 are consistent in a vertical direction crossing the upper surface of the substrate 100 (e.g., third direction Z), but are not limited thereto. According to characteristics of an etching process (or patterning process) for forming the first nanosheet stack NSS1 and the second nanosheet stack NSS2, the width of the first nanosheet stack NSS1 and the width of the second nanosheet stack NSS2 may be reduced away from the substrate 100.

The first nanosheet stack NSS1 and the second nanosheet stack NSS2 may each include silicon (Si) or germanium (Ge) that is an element semiconductor material. Alternatively, the first nanosheet stack NSS1 and the second nanosheet stack NSS2 may each include compound semiconductor, e.g., a group IV-IV compound semiconductor or group III-V compound semiconductor. The group IV-IV compound semiconductor may include, for example, a binary compound or a ternary compound including at least two of carbon (C), silicon (Si), germanium (Ge), and tin (Sn), or a compound having a group IV element doped on the above materials. The group III-V compound semiconductor may include, for example, one of a binary compound, a ternary compound, and a quaternary compound which is formed by combining at least one of group III elements, e.g., aluminum (Al), gallium (Ga), and indium (In) with at least one of group V elements, e.g., phosphor (P), arsenic (As), and antimony (Sb).

Alternatively, at least one of the first nanosheet stack NSS1 and the second nanosheet stack NSS2 may include a two-dimensional (2D) semiconductor material. The 2D semiconductor material denotes a semiconductor material having a two-dimensional crystallization structure, and may have a monolayer or multilayer structure. Each layer in the 2D semiconductor material may have a thickness of an atomic level.

In the semiconductor device, at least one of the first nanosheet stack NSS1 and the second nanosheet stack NSS2 may include the 2D semiconductor device and a shorter channel length may be implemented.

The 2D semiconductor material may include, for example, at least one of graphene, black phosphorous, tellurene, and transition metal dichalcogenide (TMD). The graphene is a material in which carbon atoms are two-dimensionally coupled to form a hexagonal honeycomb structure, and has higher electrical mobility and superior thermal characteristics as compared with Si, is chemically stabilized, and has large surface area. In addition, the black phosphorous is a material in which black phosphorous atoms are two-dimensionally coupled.

The TMD may be expressed as, for example, MX_{2,} where M denotes a transition metal and X denotes a chalcogen element. For example, M may include Mo, W, Nb, V, Ta, Ti, Zr, Hf, Tc, Re, etc., and X may include S, Se, Te, etc. Therefore, TMD may include, for example, MoS₂, MoSe₂, MoTe₂, WS₂, WSe₂, WTe₂, ZrS₂, ZrSe₂, HfS₂, HfSe₂, NbSe₂, ReSe₂, etc. Alternatively, TMD may not be expressed as MX₂. In this case, for example, TMD may include CuS that is a compound of Cu, that is, transition metal, and S, that is, chalcogen element. In addition, TMD may be a chalcogenide material including a non-transition metal. The non-transition metal may include, for example, Ga, In, Sn, Ge, Pb, etc. In this case, TMD may include a compound of non-transition metal such as Ga, In, Sn, Ge, Pb, etc. and a chalcogen element such as S, Se, and Te. For example, TMD may include SnSe₂, GaS, GaSe, GaTe, GeSe, In₂Se₃, InSnS₂, etc.

As described above, TMD may include one metal element from Mo, W, Nb, V, Ta, Ti, Zr, Hf, Tc, Re, Cu, Ga, In, Sn, Ge, and Pb and one chalcogenide element from S, Se, and Te. However, above-described materials are example, and other materials may be used as TMD materials.

For convenience of description, it is described that the first nanosheet stack NSS1 and the second nanosheet stack NSS2 are respectively Si patterns.

In some embodiments, the first nanosheet stack NSS and the second nanosheet stack NSS may be arranged at the same level as each other. Here, arranging at the same level may denote arranging at the same height based on the upper surface of the substrate 100. For example, as shown in the drawings, the first nanosheets 111, 112, and 113 and the second nanosheets 211, 212, and 213 may be arranged at the same height.

In some embodiments, the first nanosheet stack NSS1 and the second nanosheet stack NSS2 may be formed at the same level as each other. Here, forming at the same level may denote forming through the same manufacturing processes. For example, the first nanosheet stack NSS1 and the second nanosheet stack NSS2 may include the same materials and/or the same material configuration.

In some embodiments, a first fin activation region 110 may be formed between the substrate 100 and the first nanosheet stack NSS1. The first fin activation region 110 may protrude from the upper surface of the substrate 100 and extend in the first direction X. The first fin activation region 110 may be formed by partially etching the substrate 100 or may be an epitaxial layer grown from the substrate 100. The first nanosheets 111, 112, and 113 may be sequentially stacked above the upper surface of the first fin activation region 110.

In some embodiments, a second fin activation region 210 may be formed between the substrate 100 and the second nanosheet stack NSS2. The second fin activation region 210 may protrude from the upper surface of the substrate 100 and extend in the first direction X. The second fin activation region 210 may be formed by partially etching the substrate 100 or may be an epitaxial layer grown from the substrate 100. The second nanosheets 211, 212, and 213 may be sequentially stacked on the upper surface of the second fin activation region 210.

In some embodiments, the semiconductor device may further include an isolation layer 101 formed on the substrate 100. The isolation layer 101may include, but is not limited to, at least one of silicon oxide, silicon nitride, silicon oxynitride, and a combination thereof. For example, the isolation layer 101 may include a silicon oxide layer.

In some embodiments, the isolation layer 101 may cover at least a part of the side surface of the first fin activation region 110 and at least a part of the side surface of the second fin activation region 210.

In some embodiments, the semiconductor device may further include the dielectric wall DW arranged between the first region I and the second region II. The dielectric wall DW may extend in the first direction X and separates the first nanosheet stack NSS1 and the second nanosheet stack NSS2 from each other. For example, the dielectric wall DW may include a first side surface and a second side surface that cross the second direction Y and are opposite to each other. The first nanosheet stack NSS1 may extend in the first direction X on the first side surface of the dielectric wall DW, and the second nanosheet stack NSS2 may extend in the first direction X on the second side surface of the dielectric wall DW. In some embodiments, the first nanosheet stack NSS1 may come into contact with the first side surface of the dielectric wall DW and the second nanosheet stack NSS2 may come into contact with the second side surface of the dielectric wall DW.

In some embodiments, a ratio of a height H with respect to a width W of the dielectric wall W may be about 9 or greater, or 10 or greater. The width of the dielectric wall DW may be about 50 nm or less, for example, 30 nm or less. Because the width of the dielectric wall DW is small, a distance between the first nanosheet stack NSS1 and the second nanosheet stack NSS2 may be further reduced, and the size of the semiconductor device may be greatly reduced.

In some embodiments, the dielectric wall DW may be formed of an insulating material having a dielectric constant of 3 or less. The semiconductor device may have the dielectric wall DW having a lower dielectric constant, and thus, the distance between the NFET and PFET may be reduced.

In some embodiments, the dielectric wall DW may include amorphous boron nitride. In other words, the dielectric wall DW may include a boron nitride layer including amorphous phase. The boron nitride layer may have a peak half width of 20 cm⁻¹ or greater in a region of 1350 cm⁻¹ to 1400 cm⁻¹ of a Raman spectrum. Here, the boron nitride layer may have boron of which a ratio with respect to nitrogen is 0.9 to 1.1, and may have a density of 1.6 g/cm³ or greater. The boron nitride layer including amorphous phase may have a dielectric constant of 3 or less. However, one or more embodiments are not limited thereto. The dielectric wall DW may further include silicon oxide, silicon nitride, silicon oxynitride, and a combination thereof. Even when the dielectric wall DW further includes a material other than the amorphous boron nitride, the dielectric wall DW may dominantly include amorphous boron nitride. Here, the term ‘dominant’ may denote that content of the amorphous boron nitride is the largest from among the materials included in the dielectric wall DW.

The amorphous boron nitride may have a dielectric constant of about 2.5 or less, e.g., about 2.3 or less. Crystalline hexagonal boron nitride has a dielectric constant of 3.1 to 3.8, whereas the amorphous boron nitride has a dielectric constant of about 2.5 or less, and thus, the interference between the NFET and PFET may be more effectively reduced.

Also, the amorphous boron nitride has a height that is greater as compared with the width, and thus, may be formed through an atomic layer deposition process. When the dielectric wall DW having the height that is greater as compared with the width is formed through a difference process, other than the atomic layer deposition (ALD) process, e.g., chemical vapor deposition (CVD) process, a void in which the material is not filled may be generated in the dielectric wall DW. The void may degrade stability, strength, etc. of the semiconductor device. The amorphous boron nitride may be formed through the ALD process, and thus, the dielectric wall DW according to the embodiment may improve stability of the semiconductor device because there is no void.

In FIG. 2, the width of the dielectric wall DW may be consistent in the vertical direction (e.g., third direction Z), but is not limited thereto. According to the characteristics of the etching process (or patterning process) for forming the dielectric wall DW, the width of the dielectric wall DW may increase away from the substrate 100.

A lower surface of the dielectric wall DW may be in contact with the upper surface of the substrate 100, but is not limited thereto. In another example, the lower surface of the dielectric wall DW may be formed to be lower than the upper surface of the substrate 100 or higher than the upper surface of the substrate 100.

A first gate structure GS1 may be formed in the first region I on the substrate 100. The first gate structure GS1 may cross the first nanosheet stack NSS1. For example, the first gate structure GS1 may extend in the second direction Y on the first side surface of the dielectric wall DW. The first nanosheets 111, 112, and 113 may each extend in the first direction X and pass through the first gate structure GS1. Accordingly, the first gate structure GS1 may surround boundaries of the respective first nanosheets 111, 112, and 113, which are exposed from the dielectric wall DW.

The second gate structure GS2 may be formed in the second region II on the substrate 100. The second gate structure GS2 may cross the second nanosheet stack NSS2. For example, the second gate structure GS2 may extend in the second direction Y on the second side surface of the dielectric wall DW. The second nanosheets 211, 212, and 213 may each extend in the first direction X and pass through the second gate structure GS2. Accordingly, the second gate structure GS2 may surround boundaries of the respective second nanosheets 211, 212, and 213, which are exposed from the dielectric wall DW.

The first gate structure GS1 may include a first gate dielectric layer 132 and a first gate electrode 134, and the second gate structure GS2 may include a second gate dielectric layer 232 and a second gate electrode 234.

The first gate dielectric layer 132 may be arranged on the nanosheet stack and/or the dielectric wall DW. The first gate dielectric layer 132 may surround the circumference of the first nanosheet stack NSS1. In some embodiments, the first gate dielectric layer 132 may further extend along an upper surface of the isolation layer 101 and the side wall of the dielectric wall DW.

The second gate dielectric layer 132 may be arranged on the nanosheet stack and/or the dielectric wall DW. The second gate dielectric layer 232 may surround the second nanosheet stack NSS2. In some embodiments, the second gate dielectric layer 232 may further extend along an upper surface of the isolation layer 101 and the side wall of the dielectric wall DW.

The first gate dielectric layer 132 and the second gate dielectric layer 232 may each include, for example, at least one of silicon oxide, silicon oxynitride, silicon nitride, or a high-K material having a greater dielectric constant that the silicon oxide. The high-K material may include, for example, but is not limited to, at least one of hafnium oxide, zirconium oxide, lanthanum oxide, aluminum oxide, titanium oxide, strontium titanium oxide, lanthanum aluminum oxide, yttrium oxide, hafnium oxynitride, zirconium oxynitride, lanthanum oxynitride, aluminum oxynitride, titanium oxynitride, strontium titanium oxynitride, lanthanum aluminum oxynitride, yttrium oxynitride, and combinations thereof.

The semiconductor device according to some embodiments may include a negative capacitance (NC) FET using a negative capacitor. For example, the first gate dielectric layer 132 and/or the second gate dielectric layer 232 may include a ferroelectric material layer having ferroelectric characteristics, and a paraelectric material layer having paraelectric characteristics.

The ferroelectric material layer may have a negative capacitance, and the paraelectric material layer may have a positive capacitance. For example, when two or more capacitors are connected in series and the capacitance of each of the capacitors have the positive value, the total capacitance is reduced less than the capacitance of individual capacitor. On the other hand, when at least one of the capacitances of the two or more capacitors connected in series has a negative value, the total capacitance has a positive value and may be greater than an absolute value of the individual capacitance.

When the ferroelectric material layer having a negative capacitance and the paraelectric material layer having a positive capacitance are connected in series, the total capacitance of the ferroelectric material layer and the paraelectric material layer connected in series may increase. By using the increase in the total capacitance value, the transistor including the ferroelectric material layer may have a subthreshold swing (SS) less than about 60 mV/decade at room temperature.

The ferroelectric material layer may have ferroelectric characteristics. The ferroelectric material layer may include, for example, at least one of hafnium oxide, hafnium zirconium oxide, barium strontium titanium oxide, barium titanium oxide, and lead zirconium titanium oxide. Here, for example, the hafnium zirconium oxide may be hafnium oxide doped with zirconium (Zr). In another example, the hafnium zirconium oxide may be a compound of hafnium (Hf), zirconium (Zr), and oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The kind of the dopant included in the ferroelectric material layer may vary depending on a kind of ferroelectric material layer included in the ferroelectric material layer.

When the ferroelectric material layer includes hafnium oxide, the dopant included in the ferroelectric material layer may include, for example, at least one of Gd, Si, Zr, Al, and Y.

When the dopant is Al, the ferroelectric material layer may include Al of about 3 at % to about 8 at %. Here, the ratio of the dopant may be a ratio of Al with respect to the sum of Hf and Al.

When the dopant is Si, the ferroelectric material layer may include Si of about 2 at % to about 10 at %. When the dopant is Y, the ferroelectric material layer may include Y of about 2 at % to about 10 at %. When the dopant is Gd, the ferroelectric material layer may include Gd of about 1 at % to about 7 at %. When the dopant is Zr, the ferroelectric material layer may include Zr of about 50 at % to about 80 at %.

The paraelectric material layer may have paraelectric characteristics. The paraelectric material layer may include, for example, at least one of silicon oxide and a metal oxide having high-K. The metal oxide included in the paraelectric material layer may include, for example, at least one of hafnium oxide, zirconium oxide, and aluminum oxide, but is not limited thereto.

The ferroelectric material layer and the paraelectric material layer may include the same material. The ferroelectric material layer may have the ferroelectric characteristics, but the paraelectric material layer may not have the ferroelectric characteristics. For example, when the ferroelectric material layer and the paraelectric material layer include hafnium oxide, the crystallization structure of the hafnium oxide included in the ferroelectric material layer may be different from that of the hafnium oxide included in the paraelectric material layer.

The ferroelectric material layer may have a thickness having ferroelectric characteristics. The thickness of the ferroelectric material layer may be, for example, 0.5 nm to 10 nm, but is not limited thereto. Because a critical thickness representing the ferroelectric characteristics may vary depending on each ferroelectric material, the thickness of the ferroelectric material layer may vary depending on the ferroelectric material.

For example, the first gate dielectric layer 132 and/or the second gate dielectric layer 232 may include one ferroelectric material layer. In another example, the first gate dielectric layer 132 and/or the second gate dielectric layer 232 may include a plurality of ferroelectric material layers spaced apart from each other. The first gate dielectric layer 132 and/or the second gate dielectric layer 232 may each have a stacked layer structure in which a plurality of ferroelectric material layers and a plurality of paraelectric material layers are alternately stacked.

The first gate electrode 134 may be arranged on the first gate dielectric layer 132. The first gate dielectric layer 132 may be arranged between the first nanosheet stack NSS1 and the first gate electrode 134.

The second gate electrode 234 may be arranged on the second gate dielectric layer 232. The second gate dielectric layer 232 may be arranged between the second nanosheet stack NSS2 and the second gate electrode 234.

The first gate electrode 134 and the second gate electrode 134 may be each formed, for example, through a replacement process, but are not limited thereto. The first gate electrode 134 and the second gate electrode 234 are each a single layer, but are not limited thereto, and the first gate electrode 134 and the second gate electrode 234 may each be formed by stacking a plurality of conductive layers.

In some embodiments, the dielectric wall DW may extend in the first direction X and separate the first gate structure GS1 from the second gate structure GS2. For example, the upper surface of the dielectric wall DW may be formed to be higher than the upper surface of the first gate structure GS1 and the upper surface of the second gate structure GS2.

A first gate spacer 140 may be formed on the first nanosheet stack NSS1 and the first gate structure. The first gate spacer 140 may extend along the side surface of the first gate structure GS1. In some embodiments, a part of the first gate dielectric layer 132 may be arranged between the first gate dielectric layer 134 and the first gate spacer 140. For example, as shown in FIG. 3, the first gate dielectric layer 132 may further extend along at least a part of the inner side surface of the first gate spacer 140. The first gate dielectric layer 132 may be formed by a replacement process, but is not limited thereto.

The second gate spacer 240 may be formed on the second nanosheet stack NSS2 and the second gate structure GS2. The second gate spacer 240 may extend along the side surface of the second gate structure GS2. In some embodiments, a part of the second gate dielectric layer 232 may be arranged between the second gate electrode 23 and the second gate spacer 240. For example, as shown in FIG. 4, the second gate dielectric layer 232 may further extend along at least a part of the inner side surface of the second gate spacer 240. The second gate dielectric layer 232 may be formed by a replacement process, but is not limited thereto.

The first gate spacer 140 and the second gate spacer 240 may each include, for example, at least one of silicon nitride, silicon oxynitride, silicon oxycarbide, silicon boron nitride, silicon carbon boron nitride, silicon oxycarbonitride, and a combination thereof. For example, the first gate spacer 140 and the second gate spacer 240 may each include a silicon nitride layer.

A first source/drain pattern 160 may be formed on at least one side surface (e.g., both side surfaces) of the first gate structure GS1. The first source/drain pattern 160 may come into contact with the first nanosheet stack NSS1. For example, each of the first nanosheets 111, 112, and 113 may come into contact with the first source/drain pattern 160 through the first gate structure GS1 and the first gate spacer 140. The first source/drain pattern 160 may be electrically separated from the first gate electrode 134 by the first gate spacer 140 and/or the first gate dielectric layer 132.

In some embodiments, the first source/drain pattern 160 may include an epitaxial layer. For example, the first source/drain pattern 160 may be formed from the first nanosheet stack NSS1 by an epitaxial growth method. The first source/drain pattern 160 may be provided as a source/drain region of a field-effect transistor (FET) formed in the first region I.

When the first region I is an NFET region, the first source/drain pattern 160 including the epitaxial layer may include n-type impurities (e.g., P, Sb, or As) or impurities for preventing dispersion of the n-type impurities. When the first region I is the NFET region, the first source/drain pattern 160 including the epitaxial layer may further include a tensile stress material. For example, when the first nanosheet stack NSS1 includes Si pattern, the first source/drain pattern 160 may include a material having a less lattice constant (e.g., silicon carbide (SiC)) than that of Si.

In some embodiments, the first source/drain pattern 160 may include a metal material such as nickel (Ni), palladium (Pd), aurum (Au), titanium (Ti), argentum (Ag), aluminum (Al), tungsten (W), copper (Cu), manganese (Mn), zirconium (Zr), etc. The first source/drain pattern 160 may be provided as a source/drain electrode.

A second source/drain pattern 260 may be formed on at least one side surface (e.g., both side surfaces) of the second gate structure GS2. The second source/drain pattern 260 may come into contact with the second nanosheet stack NSS2. For example, each of the second nanosheet stack NSS2 211 to 213 may be connected to the second source/drain pattern 260 through the second gate structure GS2 and the second gate spacer 240. The second source/drain pattern 260 may be electrically separated from the second gate electrode 234 by the second gate spacer 240 and/or the second gate dielectric layer 232.

In some embodiments, the second source/drain pattern 260 may include an epitaxial layer. For example, the second source/drain pattern 260 may be formed from the second nanosheet stack NSS2 by an epitaxial growth method. The second source/drain pattern 260 may be provided as a source/drain region of an FET formed in the second region II.

When the second region II is the PFET, the second source/drain pattern 260 including the epitaxial layer may include p-type impurities (e.g., B, In, Ga, or Al) or impurities for preventing dispersion of the p-type impurities. When the second region II is the PFET region, the second source/drain pattern 260 including the epitaxial layer may further include a compressive stress material. For example, when the second nanosheet stack NSS2 includes Si pattern, the second source/drain pattern 260 may include a material having greater lattice constant (e.g., SiGe) than that of Si.

In some embodiments, the second source/drain pattern 260 may include a metal material such as Ni, Pd, Au, Ti, Ag, Al, W, Cu, Mn, Zr, etc. The second source/drain pattern 260 may be provided as a source/drain electrode coming into contact with the nanosheet stack.

An interlayer insulating layer 180 may be formed on the dielectric wall DW, the first gate structure GS1, the second gate structure GS2, the first source/drain pattern 160, and the second source/drain pattern 260. For example, the interlayer insulating layer 180 may cover the dielectric wall DW, the first gate structure GS1, the second gate structure GS2, the first source/drain pattern 160, and the second source/drain pattern 260.

The interlayer insulating layer 180 may include, for example, silicon oxide, silicon nitride, silicon oxynitride, silicon oxycarbide, silicon boron nitride, silicon boron carbon nitride, silicon oxycarbon nitride, and a low-K material having a less dielectric constant than that of the silicon oxide, but is not limited thereto. The low-k material may include, for example, flowable oxide (FOX), torene silazene (TOSZ), undoped silica glass (USG), borosilica glass (BSG), phosphosilica glass (PSG), borophosphosilica glass (BPSG), plasma enhanced tetra ethyl ortho silicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SiLK, polyimide, porous polymeric material, and a combination thereof, but is not limited thereto.

A first gate contact GC1 may be electrically connected to the first gate structure GS1. For example, the first gate contact GC1 may extend in the third direction Z and pass through the interlayer insulating layer 180, and may be connected to the upper surface of the first gate electrode 134.

The second gate contact GC2 may be electrically connected to the second gate structure GS2. For example, the second gate contact GC2 may extend in the third direction Z and pass through the interlayer insulating layer 180, and may be connected to the upper surface of the second gate electrode 234.

The first gate contact GC1 and the second gate contact GC2 may each include a metal material, for example, Co, Ti, Ta, Ru, W, or CoWP, but is not limited thereto. For example, the first gate contact GC1 and the second gate contact GC2 may each include Co.

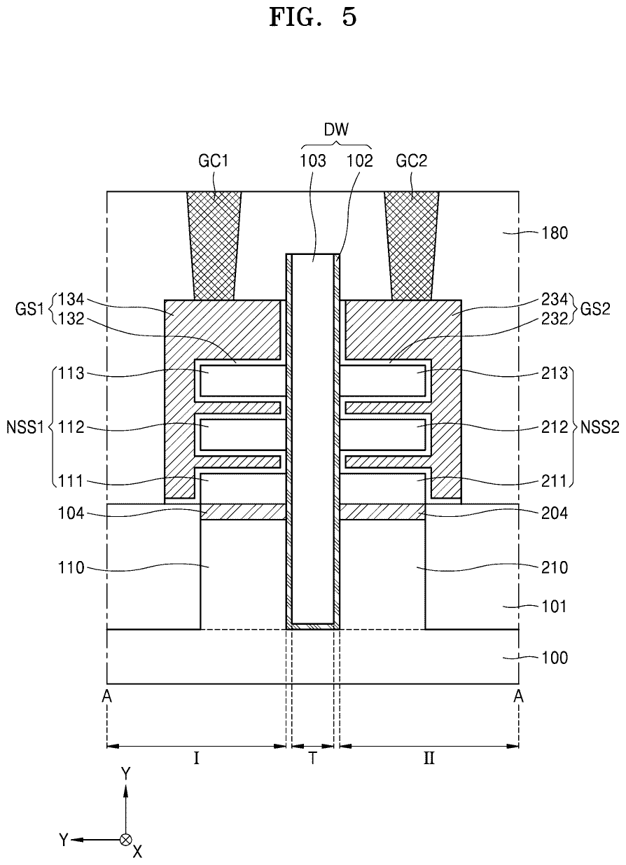

FIG. 5 is a cross-sectional view of a semiconductor device according to another embodiment. When comparing with FIG. 2 and FIG. 5, the dielectric wall DW included in the semiconductor device of FIG. 5 may include a plurality of layers. For example, the dielectric wall DW may include a first film 102 that is arranged on lower surface and both side surfaces of the dielectric wall DW and includes a trench T, and a second film 103 filling the trench T. The first film 102 may be formed of a material other than amorphous boron nitride, and the second film 103 may be formed of amorphous boron nitride. A width of the first film 102 in the second direction may be greater than that of the second film 103. That is, the dielectric wall DW may dominantly contain amorphous boron nitride.

The amorphous boron nitride has a small dielectric constant so as to reduce interference between the NFET and the PFET, but may be low in rigidity because of low Young's modulus. The second film 103 includes a material having a greater Young's modulus than that of the amorphous boron nitride, to thereby improve rigidity of the semiconductor device. For example, the first film 102 may include at least one of silicon oxide, silicon nitride, silicon oxynitride, and a combination thereof. In some embodiments, the first film 102 may include silicon nitride.

When comparing FIG. 2 with FIG. 5, the semiconductor device of FIG. 5 may further include a first insulating layer 104 arranged in the first region I on the substrate 100, and a second insulating layer 204 arranged in the second region II on the substrate 100.

The first insulating layer 104 may be interposed between the substrate 100 and the first nanosheet stack NSS1. For example, the first insulating layer 104 may be interposed between the first fin activation region 110 and the first sheet pattern 111 that is the lowermost layer from among the first nanosheets 111, 112, and 113. The first insulating layer 104 may extend in the first direction X. The first nanosheet stack NSS1 may be electrically separated from the substrate 100 and/or the first fin activation region 110 due to the first insulating layer 104.

The second insulating layer 204 may be interposed between the substrate 100 and the second nanosheet stack NSS2. For example, the second insulating layer 204 may be interposed between the second fin activation region 210 and a bridge pattern (e.g., fifth sheet pattern 211) arranged at the lowermost part of the second nanosheets 211, 212, and 213. The second insulating layer 204 may extend in the first direction X. The second nanosheet stack NSS2 may be electrically separated from the substrate 100 and/or the second fin activation region 210 due to the second insulating layer 204.

At least one of the first insulating layer 104 and the second insulating layer 204 may include the same material as that of the first film 102 of the dielectric wall DW. For example, each of the first insulating layer 104 and the second insulating layer 204 may include, for example, at least one of silicon oxide, silicon nitride, silicon oxynitride, and a combination thereof, but is not limited thereto. For example, the first insulating layer 104 and the second insulating layer 204 may each include a silicon nitride layer.

In some embodiments, the first insulating layer 104 and the second insulating layer 204 may be at the same level as each other. In some embodiments, the first insulating layer 104 and the second insulating layer 204 may be formed at the same level as each other.

The upper surface of the isolation layer 101 may be coplanar with the upper surface of the first insulating layer 104 and the upper surface of the second insulating layer 204, but is not limited thereto. In another example, the upper surface of the isolation layer 101 may be formed lower than the upper surface of the first insulating layer 104 and the upper surface of the second insulating layer 204, or may be higher than the upper surface of the first insulating layer 104 and the upper surface of the second insulating layer 204.

In some embodiments, the dielectric wall DW may extend in the first direction X and may separate the first insulating layer 104 and the second insulating layer 204 from each other. For example, the lower surface of the dielectric wall DW may be lower than the lower surface of the first insulating layer 104 and the lower surface of the second insulating layer 204.

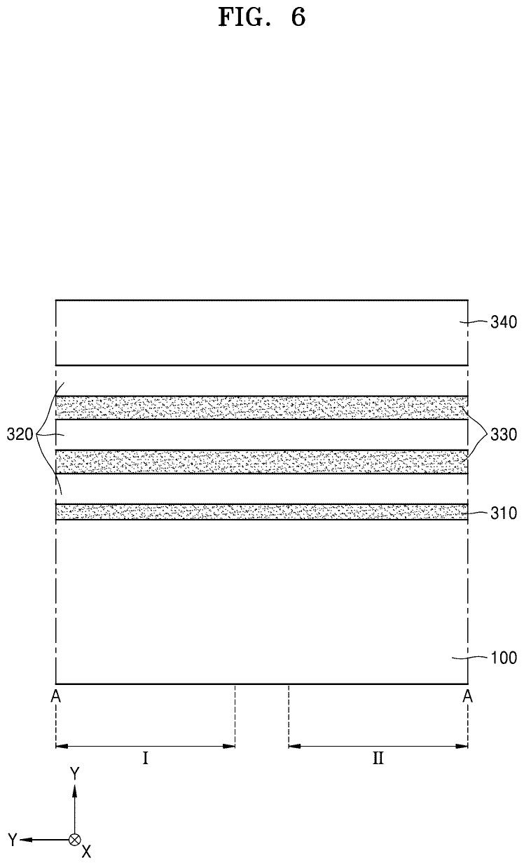

FIGS. 6 to 13 are reference diagrams for illustrating a method of manufacturing the semiconductor device of FIG. 5. For convenience of description, redundant parts are simply described or omitted.

Referring to FIG. 6, a first sacrificial layer 310, a plurality of semiconductor layers 320, a plurality of second sacrificial layers 330, and a protective layer 340 may be formed on the substrate 100.

The first sacrificial layer 310 may be formed on the substrate 100. The first sacrificial layer 310 may have an etch selectivity with respect to the substrate 100 and the semiconductor layers 320. For example, the substrate 100 and the semiconductor layer 320 may include Si, and the first sacrificial layer 310 may include SiGe.

The plurality of semiconductor layers 320 and the plurality of second sacrificial layers 330 may be formed on the first sacrificial layer 310. A plurality of semiconductor layers 320 and a plurality of sub-sacrificial layers may be alternately stacked on the first sacrificial layer 310 one-by-one. Each of the second sacrificial layers 330 is arranged between the semiconductor layers 320, and may separate the semiconductor layers 320 from each other in a vertical direction (e.g., third direction Z).

The second sacrificial layer 330 may include a transition metal element. The transition metal element may include, for example, at least one metal material from Mo, W, Nb, V, Ta, Ti, Zr, Hf, Tc, Re, and Cu. For example, the second sacrificial layer 330 may include Mo or W.

In some embodiments, the second sacrificial layer 330 may include an oxide of transition metal element. For example, the second sacrificial layer 330 may include molybdenum dioxide (MoO2) or tungsten dioxide (WO2).

The protective layer 340 may be formed on the semiconductor layers 320 and the second sacrificial layers 330. The protective layer 340 may include various materials protecting the semiconductor layer 320 and/or the second sacrificial layer 330 in post-processes.

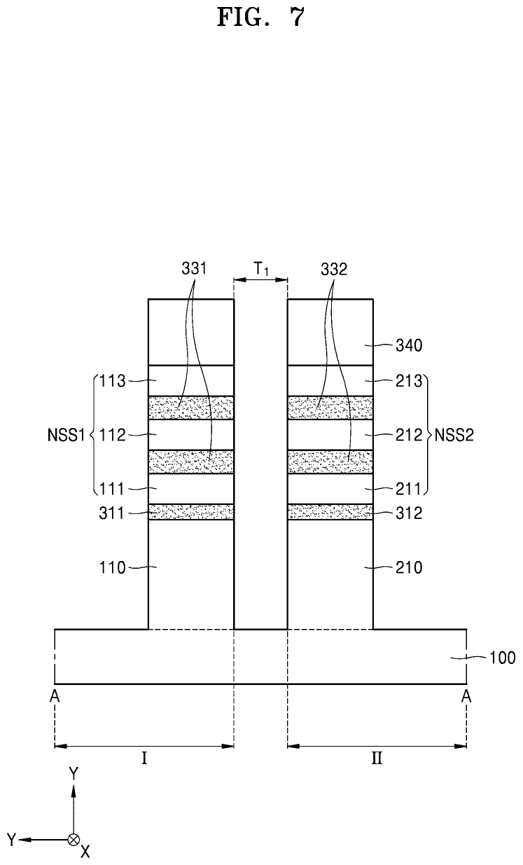

Referring to FIG. 7, a first trench T1 that passes through the first sacrificial layer 310, the plurality of semiconductor layers 320, the plurality of second sacrificial layers 330, and the protective layer 340 to expose the substrate 100 is formed, and accordingly, a first sacrificial pattern 311, a second sacrificial pattern 312, the first nanosheet stack NSS1, third sacrificial patterns 331, the second nanosheet stack NSS2, and fourth sacrificial patterns 332 may be formed on the substrate 100.

The first sacrificial pattern 311, the second sacrificial pattern 312, the first nanosheet stack NSS1, the third sacrificial patterns 331, the second nanosheet stack NSS2, and the fourth sacrificial patterns 332 may each extend in the first direction X. For example, a patterning process for patterning the first sacrificial layer 310, the semiconductor layers 320, the second sacrificial layers 330, and the protective layer 340 of FIG. 6 may be performed. The first sacrificial layer 310 patterned in the first region I may become the first sacrificial pattern 311, and the first sacrificial layer 310 patterned in the second region II may become the second sacrificial pattern 312. The semiconductor layers 320 patterned in the first region I may become the first nanosheet stack NSS1, and the second sacrificial layers 330 patterned in the second region II may become the third sacrificial patterns 331 alternately stacked with the first nanosheet stack NSS1. Also, the semiconductor layers 320 patterned in the second region II may become the second nanosheet stack NSS2, and the second sacrificial layers 330 patterned in the second region II may become the fourth sacrificial patterns 332 alternately stacked with the second nanosheet stack NSS2.

In some embodiments, during the process of etching the first sacrificial layer 310, the substrate 100 may be partially etched to form the first fin activation region 110 in the first region I and the second fin activation region 210 in the second region II.

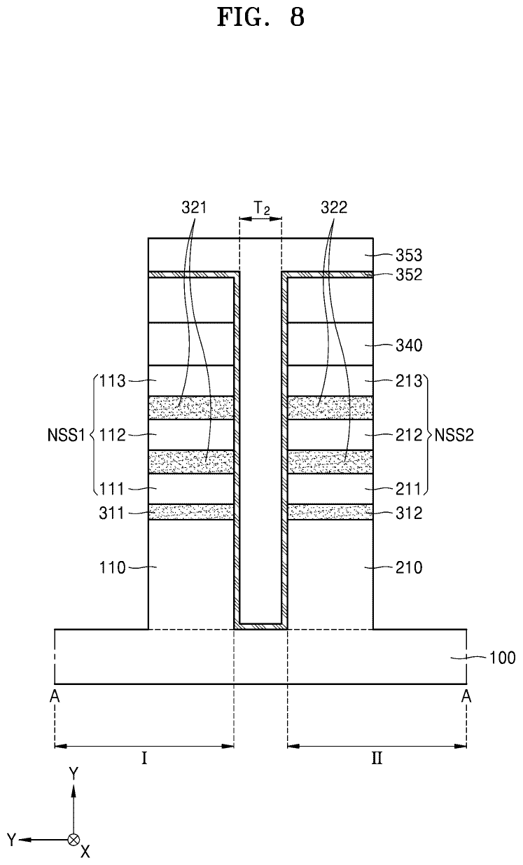

Referring to FIG. 8, filling insulating layers 352 and 353 covering the first nanosheet stack NSS1 and the second nanosheet stack NSS2 may be formed. The filling insulating layers 352 and 353 may fill the region between the first nanosheet stack NSS1 and the second nanosheet stack NSS2. The filling insulating layers 352 and 353 may include the first filling insulating layer 352 formed on the region between the first nanosheet stack NSS1 and the second nanosheet stack NSS2 while forming a second trench T2and the second filling insulating layer 353 filling the second trench T2 formed by the first filling insulating layer 352. The first filling insulating layer 352 may include, but is not limited to, at least one of silicon oxide, silicon oxynitride, silicon nitride, and a combination thereof. For example, the first filling insulating layer 352 may include a silicon nitride layer. The second filling insulating layer 353 may include amorphous boron nitride.

The filling insulating layer 352 may be formed through a CVD process, and the second filling insulating layer 353 may be formed through the ALD process. When the semiconductor device does not include the first and second sacrificial patterns, the filling insulating layer may be formed as an amorphous boron nitride layer. Here, the filling insulating layers 352 and 353 may be at least partially formed through the ALD process. When the filling insulating layers 352 and 353 are only formed through the CVD process, a void that is not filled with a material may be generated during the process of stacking the filling insulating layers 352 and 353. However, in some embodiments, the filling insulating layers 352 and 353 are at least partially formed through the ALD process, the region between the first nanosheet stack NSS1 and the second nanosheet stack NSS2 may be filled without a void.

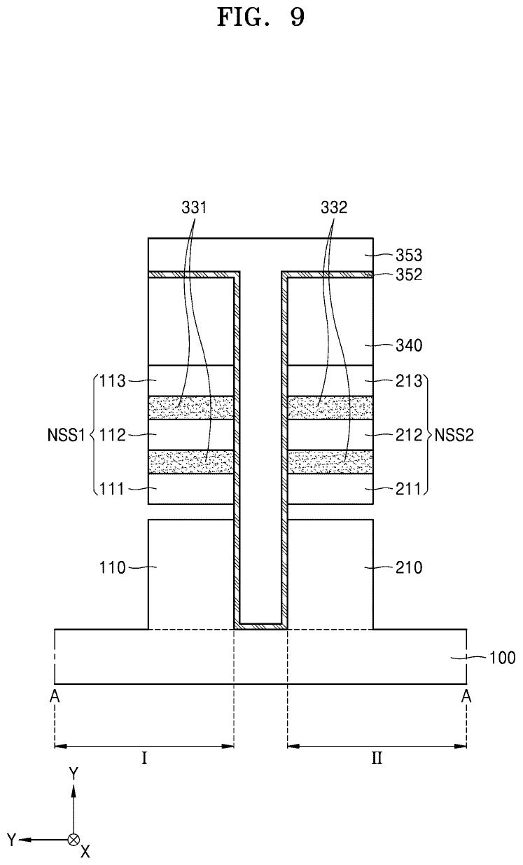

Referring to FIG. 9, the first sacrificial pattern 311 and the second sacrificial pattern 312 may be removed. Because the first sacrificial pattern 311 and the second sacrificial pattern 312 may each have an etch selectivity with respect to the substrate 100 and the nanosheet stacks NSS1 and NSS2, the first and second sacrificial patterns 311 and 132 may be selectively removed. In some embodiments, the third sacrificial patterns 331 and the fourth sacrificial patterns 332 may not be removed.

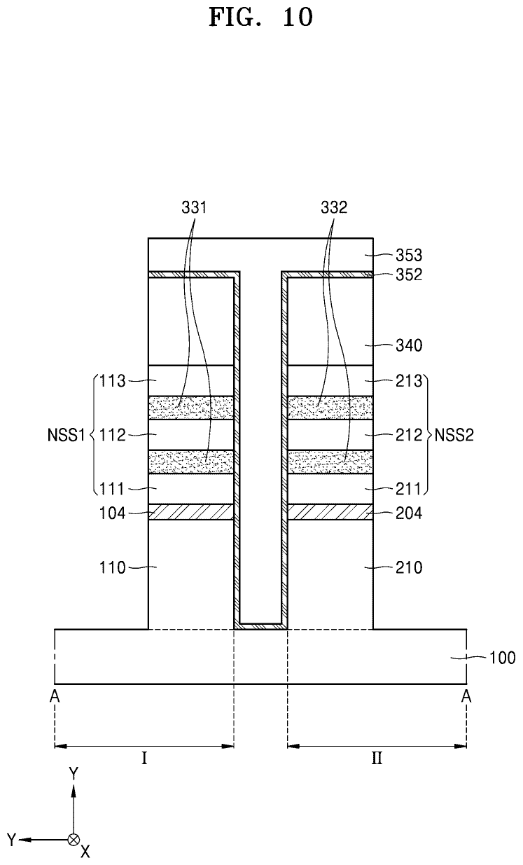

Referring to FIG. 10, the first insulating layer 104 and the second insulating layer 204 may be formed. The first insulating layer 104 may fill the region from which the first sacrificial pattern 311 is removed, and the second insulating layer 204 may fill the region from which the second sacrificial pattern 312 is removed. The first insulating layer 104 and the second insulating layer 204 may include the same material as that of the first filling insulating layer 352. For example, the first insulating layer 104 and the second insulating layer 204 may each include a silicon nitride layer.

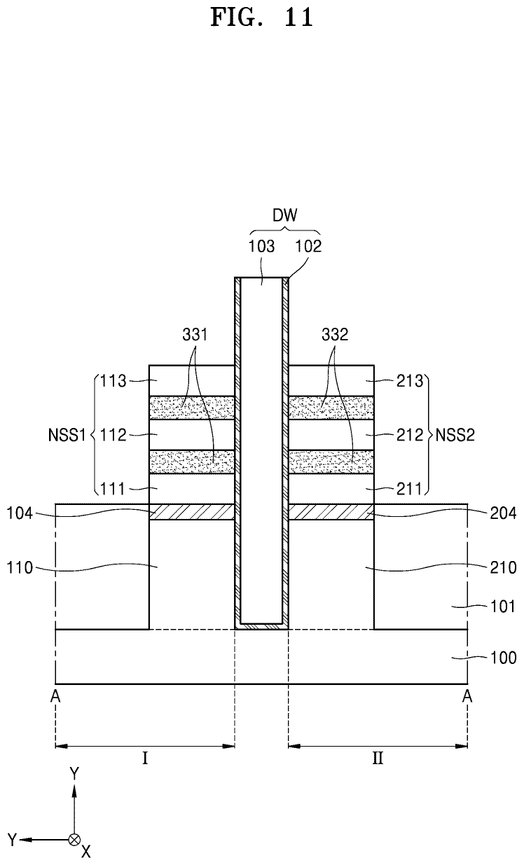

Referring to FIG. 11, the dielectric wall DW may be formed. For example, the first and second filling insulating layers 352 and 353 on the protective layer 340 may be removed to form the dielectric wall DW. Next, the protective layer 340 may be removed. As such, the dielectric wall DW separating the first nanosheet stack NSS1 and the second nanosheet stack NSS2 from each other may be formed from at least some parts of the first and second filling insulating layers 352 and 353.

In some embodiments, the isolation layer 101 may be formed on the substrate 100. The isolation layer 101 may cover at least a part of the side surface of the first fin activation region 110 and at least a part of the side surface of the second fin activation region 210. The isolation layer 101 may include, but is not limited to, at least one of silicon oxide, silicon nitride, silicon oxynitride, and a combination thereof. For example, the isolation layer 101 may include a silicon oxide layer.

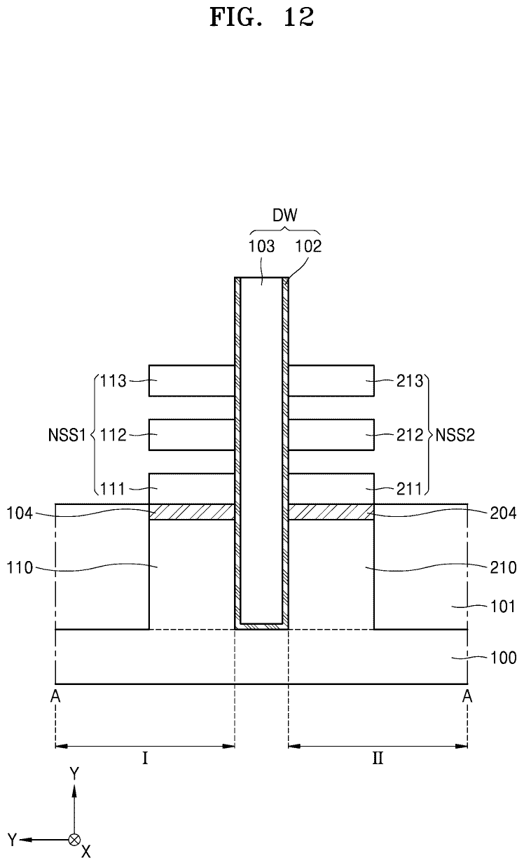

Referring to FIG. 12, the third sacrificial patterns 331 and the fourth sacrificial patterns 332 may be removed. Each of the third sacrificial patterns 331 and the fourth sacrificial patterns 332 may be selectively removed with respect to the first nanosheet stack NSS1 and the second nanosheet stack NSS2.

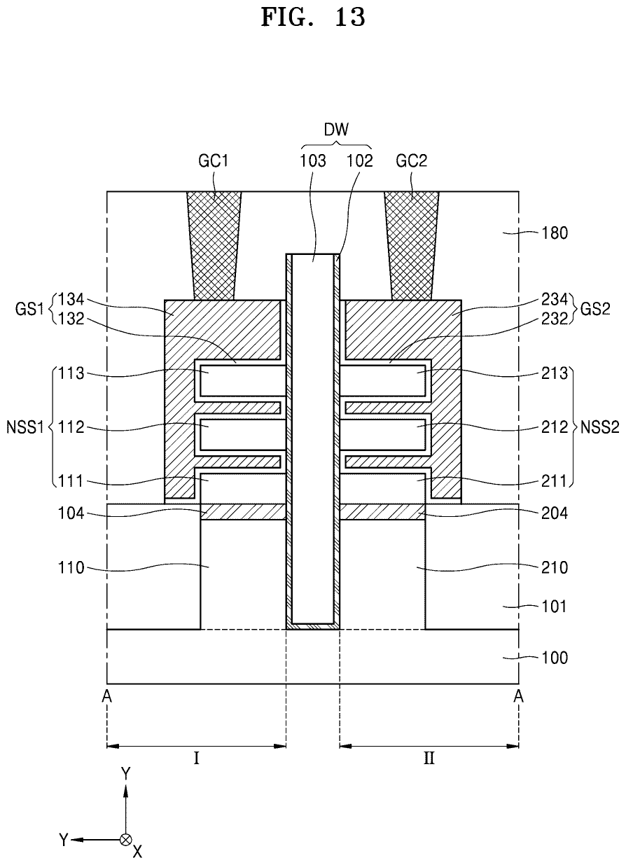

Referring to FIG. 13, the first gate structure GS1 and the second gate structure GS2 may be formed. For example, the first gate dielectric layer 132 and the first gate electrode 134 may be sequentially stacked on the first nanosheet stack NSS1. Next, the patterning process on the first gate dielectric layer 132 and the first gate electrode 134 may be performed. As such, the first gate structure GS1 surrounding the respective boundaries of the first nanosheets 111, 112, and 113 may be formed. The second gate dielectric layer 232 and the second gate electrode 234 may be sequentially stacked on the second nanosheet stack NSS2. Next, the patterning process on the second gate dielectric layer 132 and the second gate electrode 134 may be performed. As such, the second gate structure GS2 surrounding the circumference of each of the second nanosheet stack NSS2 may be formed.

The interlayer insulating layer 180 covering the dielectric wall DW, the first gate structure GS1, and the second gate structure GS2 is formed, and the first gate contact GC1 coming into contact with the first gate structure GS1 and the second gate contact GC2 coming into contact with the second gate structure GS2 may be formed. Although not shown in the drawings, the first source/drain pattern and the second source/drain pattern may be formed during the process of manufacturing the semiconductor device.

While the semiconductor device and the method of manufacturing the semiconductor device have been particularly shown and described with reference to example embodiments thereof, it will be understood by those of ordinary skill in the art that various changes in form and details may be made therein without departing from the spirit and scope as defined by the following claims. In the specification, many details are described in detail, but they are not provided to limit the scope of the disclosure, and should be interpreted as illustrating the embodiment. Thus, the scope of the disclosure should be determined by the technical idea set forth in the claims, not by the embodiments.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a substrate including a first region and a second region;
a plurality of nanosheets extending in a first direction on the substrate,
the plurality of nanosheets including a first nanosheet stack on the first region and a second nanosheet stack on the second region,
the plurality of nanosheets in the first nanosheet stack being spaced apart from each other in a second direction,
the second direction crossing the first direction,
the plurality of nanosheets in the second nanosheet stack being spaced apart from each other in the second direction;
a first gate structure crossing the first nanosheet stack on the first region;
a second gate structure crossing the second nanosheet stack on the second region; and
a dielectric wall extending in the first direction on a portion of the substrate between the first region and the second region, the dielectric wall separating the first nanosheet stack and the second nanosheet stack from each other, and the dielectric wall including a boron nitride layer having an amorphous phase.

2. The semiconductor device of claim 1, wherein a peak half width of the boron nitride layer is 20 cm⁻¹ or more in a region of 1,350 cm⁻¹ to 1,400 cm⁻¹ of a Raman spectrum.

3. The semiconductor device of claim 1, wherein a dielectric constant of the boron nitride layer is 3 or less.

4. The semiconductor device of claim 1, wherein a ratio of a height of the dielectric wall to a width of the dielectric wall is 9 or more.

5. The semiconductor device of claim 1, wherein a width of the dielectric wall is 50 nm or less.

6. The semiconductor device of claim 1, wherein
the dielectric wall comprises a first film and a second film,
the first film contacts a lower surface of the second film, a first side surface of the second film, and a second side surface of the second film, and
the first side surface of the second film is opposite the second side surface of the second film.

7. The semiconductor device of claim 6, wherein
the first film includes at least one of silicon oxide, silicon nitride, or silicon oxynitride, and
the second film includes the boron nitride layer.

8. The semiconductor device of claim 6, wherein a width of the first film is greater than a width of the second film.

9. The semiconductor device of claim 1, further comprising:
a first insulating layer between the substrate and the first nanosheet stack; and
a second insulating layer between the substrate and the second nanosheet stack.

10. The semiconductor device of claim 9, wherein the first insulating layer, the second insulating layer, or both the first insulating layer and the second insulating layer include at least one of silicon oxide, silicon nitride, or silicon oxynitride.

11. The semiconductor device of claim 1, wherein at least one of the first nanosheet stack and the second nanosheet stack is in contact with the dielectric wall.

12. The semiconductor device of claim 1, wherein the first nanosheet stack, the second nanosheet stack, or both the first nanosheet stack and the second nanosheet stack include a two-dimensional semiconductor material.

13. The semiconductor device of claim 12, wherein the two-dimensional semiconductor material includes at least one of graphene, black phosphorous, phosphorene, transition metal dichalcogenide, and tellurene.

14. The semiconductor device of claim 1, further comprising:
a first fin activation region between the substrate and the first nanosheet stack in the first region; and
a second fin activation region between the substrate and the second nanosheet stack in the second region,
wherein at least one of the first fin activation region and the second fin activation region is doped with a p-type dopant, and an other of the first fin activation region and the second fin activation region is doped with an n-type dopant.

15. A method of manufacturing a semiconductor device, the method comprising:
alternately stacking a plurality of sacrificial layers and a plurality of nanosheets on a substrate;
forming a first nanosheet stack and a second nanosheet stack by forming a first trench through the plurality of sacrificial layers and the plurality of nanosheets to expose the substrate;
forming a dielectric wall in the first trench, the forming the dielectric wall including a process of forming a boron nitride layer having an amorphous phase in the first trench using an atomic layer deposition (ALD) process;
removing the plurality of sacrificial layers; and
forming a first gate structure surrounding the first nanosheet stack and a second gate structure surrounding the second nanosheet stack.

16. The method of claim 15, wherein the boron nitride layer has a peak half width of 20 cm⁻¹ or more in a region of 1,350 cm⁻¹ to 1,400 cm⁻¹ of a Raman spectrum.

17. The method of claim 15, wherein a ratio of a height of the dielectric wall to a width of the dielectric wall is 9 or greater.

18. The method of claim 15, wherein a width of the dielectric wall is 50 nm or less.

19. The method of claim 15, wherein the forming the dielectric wall comprises:
forming a first film in the first trench, the first film defining a second trench and contact with the first nanosheet stack and the second nanosheet stack; and
forming the boron nitride layer as a second film filling the second trench.

20. The method of claim 19, wherein the first film includes at least one of silicon oxide, silicon nitride, or silicon oxynitride.
